(19) United States
(12) Patent Application Publication
(10) Pub. No.: US 2025/0132132 A1
(43) Pub. Date: Apr. 24, 2025

(54) ELECTRODE-DIELECTRIC NOZZLE FOR PLASMA PROCESSING

(71) Applicant: Lam Research Corporation, Fremont, CA (US)

(72) Inventors: Paul Konkola, West Linn, OR (US); Shaun Tyler Smith, Portland, OR (US); Yukinori Sakiyama, West Linn, OR (US); Karl Frederick Leeser, West Linn, OR (US); Ramkishan Rao Lingampalli, Danville, CA (US)

(21) Appl. No.: 18/687,069

(22) PCT Filed: Aug. 29, 2022
(86) PCT No.: PCT/US2022/041883

§ 371 Date: Feb. 27, 2024

Related U.S. Application Data
(60) Provisional application No. 63/239,664, filed on Sep. 1, 2021.

(51) Int. Cl. H01J 37/32

(52) U.S. Cl. CPC H01J 37/32385; H01J 37/32183; H01J 37/32449; H01J 37/3255; H01J 2237/002

(57) ABSTRACT

Systems and device for removing edge bead accumulated on an edge of a wafer includes a first electrode disposed in a center of a nozzle used within a process chamber and a second electrode embedded within a dielectric material that surrounds the first electrode. A first channel is defined between the first electrode and the dielectric material and is used to receive a first gas from a first gas source. A second channel is defined between the dielectric material and an outer wall of the nozzle and is used to receive a second gas. RF power source is coupled to the nozzle so as to provide RF power to the electrodes to generate plasma radicals of the first gas. An opening at a bottom of the nozzle is used to provide pressurized flow of plasma radicals toward an edge of the wafer positioned below the nozzle.

### 1. FIELD OF THE DISCLOSURE

The present embodiments relate to semiconductor wafer processing, and more particularly, to edge bead removal of the semiconductor wafer received within a wafer processing system.

### 2. DESCRIPTION OF THE RELATED ART

A typical fabrication system includes a plurality of cluster tool assemblies or processing stations. Each processing station used in the manufacturing process of a semiconductor wafer includes one or more process modules with each process module used to perform a specific manufacturing operation. Some of the manufacturing operations performed within the different process modules include, an etching operation using plasma, a deposition operation, a cleaning operation, a rinsing operation, a drying operation, etc. Some process modules are designed for processing the entire surface of the wafer, some other process modules are designed for processing the central portion of the wafer, while yet others are designed for processing the edge of the wafer. Generally, edge processing is done to remove edge bead, wherein a buildup of resist occurs along the outer edge of the wafer. The resist buildup occurs during spin cycle (e.g., spin coating). If the edge bead is not removed promptly, the edge bead can cause contamination during subsequent wafer processing.

Current approach for edge bead removal involves maintaining low pressure in the process chamber and heating the wafer to a high temperature. This approach limits throughput due to substantial chamber pressure cycling time, wafer heating time, etch time and wafer cooling time and the required hardware is expensive. Plasma direct current (DC)-arc based cutters that can cut steel are not suitable for wafer processing as an arc can damage the wafer. Further, the nozzles used for DC-arc plasma are made of metal that quickly degrade during use. The metal contamination due to the degradation is not suitable for semiconductor processing.

It is in this context that embodiments of the invention arise.

### SUMMARY

Embodiments of the disclosure include systems and methods for processing an edge of the wafer using edge bead removal process. A nozzle-based plasma jet is used along with wafer rotation to process the entire circumferential edge of the wafer. The plasma nozzle is powered by radio frequency (RF) power that can support powers and high heat loads. By design, the RF power does not deliver any arc to the wafer. The plasma nozzle includes a pair of RF electrodes to generate radicals there-between. The radicals are then directed toward the wafer by means of a pressurized jet flow. The plasma nozzle design uses a dielectric barrier to metal surfaces so as to prevent arcing and metal contamination. Further, this design of the plasma nozzle offers chemical compatibility with the plasma chemistry. With this design long life and high temperature operation can be achieved. The electrodes and the dielectric materials used in the plasma nozzle are designed to have matching coefficient of thermal expansion. The dielectric material (e.g., ceramic, such as aluminum nitride, aluminum oxynitride, silicon nitride, aluminum oxide, yttrium oxide, etc.) is chosen for its desirable break-down voltage, high resistance to thermal shock, high thermal conductivity, and high temperature operation. Cooling elements may be incorporated into the nozzle to allow high power and long-life operation.

The plasma nozzle design is capable of providing fast time constant heating and cooling. When used with a relatively high pressure gas, the design offers higher reaction product density than is possible lower pressure processes. The plasma nozzle design is capable of achieving high etch rate (at the wafer edge), as it is capable of supporting high power density into the plasma without thermally or chemically induced damage. The plasma nozzle topology offers substantial cost savings in hardware as compared to conventional technology.

In one implementation, a nozzle is disposed in a housing defined in an upper portion of a process chamber used for processing a wafer, the nozzle used for removing edge bead accumulated on the edge of the wafer. The nozzle includes a first electrode defined in a center of a body of the nozzle. A dielectric material is disposed to surround the first electrode within the body so as to define a first channel between the first electrode and the dielectric material. A first inlet coupled to a first gas source is configured to provide a first gas into the first channel. A second electrode is embedded within the dielectric material. A radio frequency (RF) power source is coupled to the nozzle and is configured to provide RF power to generate plasma of the first gas in the first channel defined between the first electrode and the second electrode. An opening is defined at a bottom of the first channel. The opening is configured to provide pressurized flow of radicals of the plasma out of the first channel toward an edge of the wafer received below the nozzle disposed in the process chamber.

In one implementation, the dielectric material is disposed in the body of the nozzle so as to define a second channel between the dielectric material and an outer wall of the nozzle. A second inlet coupled to a second gas source is configured to provide a second gas to the second channel at a first end and a second end of the second channel is disposed proximal to the opening of the first channel. The second gas acts as a carrier gas to carry the radicals of the plasma supplied through the opening of the first channel.

IN one implementation, the second gas is an inert gas. The inert gas is one of Argon or Helium.

In one implementation, the second electrode is disposed proximate to the opening of the first channel.

In one implementation, the first electrode is coupled to the RF power source through a match network and the second electrode is electrically grounded.

In one implementation, the first electrode is electrically grounded and the second electrode is coupled to the RF power source through a match network.

In one implementation, the first electrode and the second electrode are coupled to the RF power source through a corresponding match network. The RF power source configured to switch supply of RF power between the first electrode and the second electrode.

In one implementation, chemical and thermal property of the dielectric material is substantially similar to a material used to define the first electrode and the second electrode.

In one implementation, a coefficient of thermal expansion of the dielectric material is substantially similar to the coefficient of thermal expansion of material used for the first and the second electrodes.

In one implementation, the dielectric material is any one of Aluminum nitride or Aluminum oxynitride or Silicon nitride or Aluminum oxide or yttrium oxide, and the first and the second electrode are made of anyone of Tungsten or Platinum or Molybdenum.

In one implementation, the nozzle includes a cooling element defined at an outer diameter of the dielectric material. The cooling element is designed to cover at least a portion of an outer sidewall of the dielectric material in a region where the second electrode is disposed. The cooling element includes a network of channels to flow a coolant.

In one implementation, the nozzle includes a second cooling element defined on an outer side along a bottom portion of the dielectric material. The second cooling element is disposed proximal to a second opening of the second channel defined between the dielectric material and an outer wall of the nozzle. The second cooling element includes a network of channels to flow the coolant.

In one implementation, the first gas includes a mixture of an etchant gas and a carrier gas. The etchant gas is used to generate the radicals of the plasma. The etchant gas is Oxygen.

In one implementation, the nozzle includes a set of nozzles. The set of nozzles is defined along an arc defined in the housing. Each nozzle is separated by a predefined distance from an adjacent nozzle in the set. The arc is defined in the housing to match a profile of the edge of the wafer received for removal of the edge bead.

In one implementation, the wafer is received on a chuck defined in the process chamber. The chuck is configured to move along an x-axis, a y-axis, and a z-axis to allow the edge of the wafer to be brought below the nozzle, during operation.

In one implementation, a wafer processing system having an equipment front end module, one or more loadlocks, a vacuum transfer module and a plurality of process chambers for processing the wafer is disclosed. A process chamber of the plurality of process chambers is used for removal of edge bead from an edge of a wafer. The process chamber includes a clamping chuck defined in a lower portion of the process chamber. The clamping chuck is configured to provide a support surface for the wafer received for processing and is configured to move along an x-axis, a y-axis and a z-axis. A nozzle is disposed in a nozzle housing defined in an upper portion of the process chamber. The nozzle housing is oriented over the clamping chuck. The nozzle includes a first electrode defined in a center of a body of the nozzle. A dielectric material is disposed to surround the first electrode within the body so as to define a first channel between the first electrode and the dielectric material. A first inlet coupled to a first gas source is configured to provide a first gas into the first channel. A second electrode is embedded within the dielectric material. An RF power source is coupled to the nozzle and is configured to provide RF power to generate plasma of the first gas in the first channel defined between the first electrode and the second electrode.

In one implementation, the process chamber is disposed over a loadlock of the wafer processing system. The process chamber is accessed through a chamber opening defined toward the EFEM of the wafer processing system. The chamber opening is controlled by an isolation valve defined in the EFEM.

In one implementation, the dielectric material is disposed in the body of the nozzle so as to define a second channel between the dielectric material and an outer wall of the nozzle. A second inlet coupled to a second gas source is configured to provide a second gas into the second channel at a first end. A second end of the second channel disposed proximal to the opening of the first channel. The second gas acting as a carrier gas to carry the radicals of the plasma supplied through the opening of the first channel.

In one implementation, the clamping chuck is a moveable unit and the housing with the nozzle is a stationary unit. The clamping chuck is configured to move along an x-axis, a y-axis or a z-axis to allow the edge of the wafer received thereon to be moved under the opening of the nozzle in the housing, during operation.

In one implementation, the RF power source is coupled to the first electrode via a match network and the second electrode is electrically grounded.

In one implementation, the RF power source is coupled to the second electrode via a match network and the first electrode is electrically grounded.

In one implementation, the RF power source is coupled to each one of the first electrode and the second electrode. The RF power from the RF power source is switched between the first electrode and the second electrode.

The advantage of the nozzle design with dual electrodes wherein one of the electrode is embedded in a dielectric material, uses dielectric barrier to metal surface to prevent arcing and preventing metal contamination. The nozzle design enables achieving long life operation and high temperature operation. Further, selection of material with matching coefficient of thermal expansion (CTE) for the electrode and the dielectric material supports applying high power density plasma to the wafer edge for effective removal of the edge bead. By matching the CTE of the dielectric material with that of the electrode material, chances of breakage or cracking is prevented or substantially reduced. The matching CTE, thermal conductivity and heat capacity also assists in heat dissipation at the electrode with minimized thermal shock. The dielectric material, (e.g., a ceramic, such as aluminum oxynitride or aluminum nitride or silicon nitride, aluminum oxide, yttrium oxide) are chosen for their desirable break down voltage, high resistance to thermal shock, high thermal conductivity, desirable heat capacity, and high temperature operation. Cooling elements disposed in the nozzle further assist in high power and long-life operation. The plasma jet combined with the wafer rotation or the nozzle head rotation ensures that the entirety of the circumferential edge of the wafer is processed. Other advantages include fast time for edge bead removal, constant heating and cooling, and when used with a relatively high pressure gas the nozzle design offers higher reaction product density than is possible with lower pressure processes. The plasma jet topology included in the nozzle design results in substantial cost savings in hardware as simplified hardware is required while substantially preventing thermally or chemically induced damage.

These and other advantages will be discussed below and will be appreciated by those skilled in the art upon reading the specification, drawings and the claims.

### BRIEF DESCRIPTION OF THE DRAWINGS

FIG. 1 illustrates a simplified block diagram of a semiconductor processing system in which a multi-station processing tool with a plurality of processing stations, an inbound loadlock, an outbound loadlock, and a jet edge bead removal (EBR) process chamber are employed for edge bead removal from an edge of a wafer, in accordance with one implementation.

FIG. 2A-1 illustrates a simplified overhead view of a wafer being received into the EBR system in which a single nozzle head is employed for edge bead removal, in accordance with one implementation.

FIG. 2A-2 illustrates a simplified side view of a nozzle head received within a nozzle housing positioned over an edge of the wafer received in the EBR process chamber for edge bead removal, in accordance with one implementation.

FIG. 2B-1 illustrates a simplified overhead view of a wafer received into the EBR system in which a plurality of nozzle heads are employed for edge bead removal, in accordance with an alternate implementation.

FIG. 2B-2 illustrates a simplified side view of a plurality of nozzle heads received within a nozzle housing positioned over an edge of the wafer received in the EBR process chamber for edge bead removal, in accordance with an alternate implementation.

FIG. 3 illustrates a simplified representation of an EBR process module (also referred to herein as an “jet EBR system” or simply “EBR system”) in which the nozzle head is employed for removing edge bead from the edge of a wafer, in accordance with one implementation.

FIG. 4 illustrates an expanded cross-sectional side view of a nozzle head (also referred to herein as “nozzle”) employed in the EBR system and used for removing edge bead from the edge of a wafer, in accordance with one implementation.

FIG. 4A illustrates an expanded view of a wafer undergoing edge bead removal t the edge using focused application of plasma radicals of a first gas shielded by a second gas, in accordance with one implementation.

FIGS. 5A-5C illustrate different views of the EBR system in which the nozzle head is employed to remove the edge bead from the edge of the wafer, in accordance with one implementation.

FIGS. 6A-6C illustrate variations of the nozzle head employed in the EBR system, in accordance with different implementations.

### DETAILED DESCRIPTION

In the following description, numerous specific details are set forth in order to provide a thorough understanding of the present inventive features. It will be apparent, however, to one skilled in the art that the present invention may be practiced without some or all of these specific details. In other instances, well known process operations have not been described in detail in order not to unnecessarily obscure the present invention.

Embodiments of the disclosure provide details of a nozzle head used in a process chamber within a processing tool used for removing edge bead from an edge of a wafer. Broadly speaking, the nozzle head (simply referred to as “nozzle” here-onward) is defined in a nozzle housing disposed in an upper portion (also referred to as an “upper housing portion”) of the process chamber. A lower portion (also referred to as a “lower housing portion”) of the process chamber may include components for efficient functioning of the nozzle. The components may be coupled to a controller, which provides signals for supplying the process gas for generating the plasma used for edge bead removal. In one example, the upper housing portion and/or the lower housing portion of the nozzle housing may be coupled to a support column defined in the process chamber. In another example, the upper housing portion and/or the lower housing portion of the nozzle housing may be coupled to a sidewall of the process chamber. The nozzle includes a pair of electrodes, wherein a first electrode in the pair is disposed in the center of the nozzle and a second electrode in the pair is embedded in a dielectric material that surrounds the first electrode. The dielectric material is defined to surround the first electrode so as to create a first channel between the first electrode and the dielectric material and a second channel between the dielectric material and an outer wall of the nozzle. The first channel is configured to receive a first gas from a first gas source, through a first inlet. The second channel is configured to receive a second gas from a second gas source through a second inlet.

A radio frequency (RF) power source is coupled to the nozzle so as to provide RF power to the first electrode or the second electrode. The RF power is used to generate radicals of plasma of the first gas in the first channel. The radicals are then carried out of the first channel through a first opening (i.e., first outlet) defined at the bottom of the nozzle. The second gas flows out of the second channel through a second opening (i.e., second outlet) defined at the bottom of the nozzle. The second opening is defined to be adjacent to the first opening so that the second gas flowing out of the second channel surrounds the radicals of plasma flowing out of the first opening to create a pressurized jet flow of plasma radicals so as to enhance the etch rate. The second gas acts as a shield to enable a focused application of the radicals to the edge of the wafer received below the nozzle. Further, the second gas shield prevents recombination and other reactions from occurring in the air and to prevent plasma radicals from dispersing.

The dielectric material acts as a barrier to metal surfaces to prevent arcing even when applying the RF power, and metal contamination. The dielectric material and the material used for the first and second electrodes are chosen to have matching coefficient of thermal expansion (CTE) and are capable of withstanding high temperature operation. Matching the CTE of the electrodes to the dielectric material prevents the electrodes from cracking thereby ensuring long life during high temperature operation. The dielectric material is chosen for high resistance to thermal shock, high thermal conductivity, desirable heat capacity, and high temperature operation. The long life can be further extended by incorporating cooling elements in the nozzle.

With the above general understanding of the implementation, various specific details will now be described with reference to the various drawings.

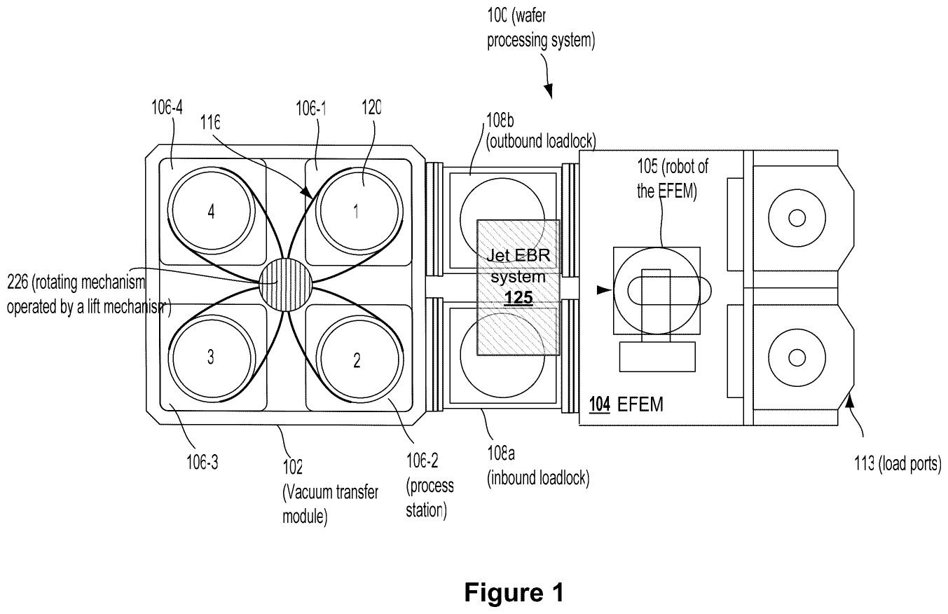

FIG. 1 illustrates a simplified block diagram of a top view of a wafer processing system 100 in which a multi-station wafer processing system is employed. The wafer processing system may be part of a larger system—e.g., a fabrication facility, wherein a plurality of such wafer processing systems are employed or wherein the wafer processing system may be employed with other wafer processing systems. The wafer processing system 100 includes a plurality of modules, such as equipment front end module (EFEM or otherwise referred to herein as atmospheric transfer module (ATM)) 104, one or more loadlocks 108, a vacuum transfer module (VTM) 102, and one or more process modules 106. Wafers for processing are brought into the wafer processing system 100 from a wafer station (not shown) that is received at a load port 113. The wafer processing system 100 illustrated in FIG. 1 shows a pair of load ports 113 although fewer or greater number of load ports 113 can also be envisioned. Access to the wafer station received at the load port 113 is provided through an isolation valve disposed at an opening defined in the EFEM 104. An end-effector of a robot 105 of the EFEM 104 is used to retrieve the wafer from the wafer station and transfer the wafer to a process module via a loadlock 108 and the VTM 102. In one implementation, the pair of loadlocks 108 includes an inbound loadlock 108a and an outbound loadlock 108b. The inbound loadlock 108a may be used to transfer an unprocessed wafer from the wafer station to the process module via the VTM 102, and the outbound loadlock 108b may be used to transfer a processed wafer from the process module 106 to the wafer station received at the load port 113 via the EFEM 104. In one implementation, the wafer processing system includes a process chamber that is a capacitively coupled plasma (CCP) process chamber that is configured to engage an edge bead removal process module for removal of edge bead from the wafer edge.

The EFEM 104 is maintained in atmospheric condition. The loadlocks 108 can be maintained either in atmospheric condition or vacuum condition depending on which state is needed for transporting the wafer. Each loadlock 108 includes a first opening defined on a first side and a second opening defined on a second side, and is connected to a vacuum pump (not shown). The first side of the loadlock 108 is coupled to the EFEM 104 and the second side is coupled to the VTM 102. A first isolation valve is engaged to provide access to the inside of the loadlock 108 via the first opening, and a second isolation valve is engaged to provide access to the loadlock 108 via the second opening. When the wafer is to be deposited from a wafer station into the loadlock 108 for onward transfer to a process module, the first isolation valve is disengaged so that the first opening remains open and the second isolation valve is engaged so that the second opening is kept closed. At this time the loadlock 108 is being operated at atmospheric condition. The robot 105 of the EFEM 104 retrieves the wafer from the wafer station and moves the wafer to the loadlock 108. Once the wafer is in the loadlock 108, the first and the second isolation valves are both engaged to keep the first and the second openings in closed position. The vacuum pump connected to the loadlock 108 is engaged to pump down the loadlock 108 to vacuum condition. Once the loadlock 108 is at vacuum, the second isolation valve of the loadlock 108 is disengaged so as to keep the second opening open while the first isolation valve continues to be engaged to keep the first opening closed. A second robot (not shown) disposed in the VTM 102 is used to retrieve the wafer from the loadlock 108 and move it to one of the process modules for processing. The VTM 102 and the process module are both maintained in vacuum. The second robot of the VTM 102 is used to move the wafer from one process module to another and between the loadlock 108 and the process module.

In one implementation where there is an inbound loadlock 108a and an outbound loadlock 108b, the wafer is moved from the wafer station into the process module through the EFEM 104 and the inbound loadlock 108a and from the process module back to the wafer station through the outbound loadlock 108b. In an alternate implementation, both the loadlocks in the pair of loadlocks 108 are used to transport the wafer between the process module and the wafer station. In yet another implementation, a first one of the loadlock 108 in the pair may be used to transport the wafer between the wafer station and the process module while a second one of the loadlock 108 in the pair may be used to transport consumable parts between consumable parts station and the process module.

In one implementation, one of the process modules 106 accessed via the VTM 102 may include multiple processing stations. In one example, the process module may include four processing stations 106-1 through 106-4. The processing stations 106-1 through 106-4 are accessed using a lifting mechanism 226. The lifting mechanism includes spider forks which are attached to a rotating mechanism, in one implementation. In one implementation, the rotating mechanism is a spindle that is operated by a spindle motor (not shown). The spindle may be disposed at the center of the process module and the spider forks of the different processing stations are connected to the spindle. In one implementation, the wafer is received on a carrier plate (not shown) and the carrier plate with the wafer is supported on a pedestal (not shown) of a processing station 106 defined in the process module, and a pair of spider forks is used to lift and lower the carrier plate with the wafer on the pedestal. In one implementation, the number of pairs of spider forks that may be engaged in a process module depends on the number of processing stations disposed in the process module. FIG. 1 illustrates a top view of a lower housing portion of one such implementation in which the process module of the wafer processing system 100 includes four processing stations (106-1 through 106-4) and four sets of spider forks for moving the four different wafer from one process station to the next. The lifting of a carrier plate with a wafer is done by, (a) moving the pair of spider forks under an outer undersurface of the carrier plate so as to support the carrier plate, (b) engaging lift pins using the lift pin control to lift the carrier plate with the wafer from the pedestal, (c) disengaging the lift pins so they retract into lift pin housing, and (d) rotating the carrier plate to the next pedestal defined on the next processing station using the spindle. The various components of the wafer processing system 100 are connected to a controller (not shown). The controller generates appropriate signals to the different components so as to coordinate the movement of the wafer from the wafer station to the process module and to the processing station within the process module.

In an alternate implementation, the wafer may be received directly on the pedestal, lifted off and lowered over the pedestal using the lift mechanism, and rotated from one process station to next using the rotating mechanism. In alternate implementation (not shown), instead of spider fork, carrier paddles or carrier blades (not shown) may be used to move the wafer received on the carrier plate from one process station to the next. The various implementations are not restricted to the use of spider forks or carrier paddles/blades as part of the lifting mechanism and that other types of lifting mechanism may also be engaged.

It should be noted that the implementation illustrated in FIG. 1 shows a single process module with 4 processing stations that can be accessed via the VTM 102, whereas in reality, there could be more than one process module that can be accessed through the VTM 102. The process modules may be multi-station process modules or may be single station process module.

In addition to the EFEM 104, the VTM 102, the loadlocks, and the process modules, the wafer processing system 100 includes a jet edge bead removal (EBR) system (or simply referred to herein as “EBR system”) 125 for removing edge bead from a wafer edge. In one implementation, the EBR system 125 is disposed on the same side of the EFEM 104 as the loadlock(s) 108. In one implementation, the EBR system 125 is disposed over the loadlock(s) 108 to minimize the footprint caused by the addition. In one implementation where the wafer processing system 100 includes two loadlocks (i.e., inbound/outbound loadlocks, or two loadlocks performing the same function of moving wafers between the wafer station and the process module, or two loadlocks performing two different functions of moving the wafers and consumable parts), the EBR system 125 may be disposed over one of the loadlocks 108 (e.g., either over the inbound loadlock 108a or over the outbound loadlock 108b) or may be disposed over both the loadlocks (e.g., inbound and outbound loadlocks 108a, 108b). FIG. 1 illustrates one implementation of the wafer processing system 100 where inbound and outbound loadlocks (108a, 108b) are disposed on a side of the EFEM 104 that is opposite to a side where the load ports 113 are disposed, and the EBR system 125 is disposed over portions of both the loadlocks (e.g., inbound and outbound loadlocks 108a, 108b).

The EBR system 125 is designed to be sufficiently small and light to allow the EBR system 125 to be easily stacked over the loadlock(s) of the existing wafer processing system leaving no additional footprints. Access to the EBR system 125 is provided through an opening on the side of the EFEM 104 where the EBR system 125 is coupled, and the opening is operated using an isolation valve. This location of the EBR system 125 in the wafer processing system 100 frees up space at the VTM 102 side for defining another process module for performing additional processing on the wafer. In this implementation, the EBR system 125 is maintained at atmospheric pressure environment. This design of the wafer processing system 100 enables the wafer to be moved from the wafer station to any of the process modules and to the EBR system 125 through the EFEM 104 and such movement of the wafer is aided using the robot 105 of the EFEM 104.

In another implementation, the EBR system 125 may be pumped down to vacuum by adding a vacuum pump to the EBR system 125. In this implementation, the EBR system 125 may act in a manner similar to the loadlocks 108, in that the EBR system 125 may be operated at above atmospheric pressure, atmospheric pressure and in vacuum. In alternate implementation, the EBR system 125 may be maintained in vacuum and be accessible through the VTM 102. In one implementation, the EBR system 125 may be defined as one of the process modules surrounding the VTM 102, in which case, one less process module is available for processing the wafer. In alternate implementation, the EBR system 125 may be disposed over any one (inbound loadlock 108a or outbound loadlock 108b) or both of the loadlocks 108a, 108b, disposed in the wafer processing system 100 with access to the EBR system 125 being provided through an opening in the VTM 102. The VTM robot may be used to move the wafer, after all the processing is done in the various process modules, to the EBR system 125 for edge bead removal. The processed and cleaned wafer is then returned to the wafer station received at the load port 113 via the outbound loadlock 108b and the EFEM 104. In yet another implementation, the EBR system 125 may be disposed over one of the process modules so as to not take up the space around the VTM 102.

The EBR system 125 includes a chuck to receive and support the wafer and a nozzle housing 126 with one or more nozzles 130 to provide pressurized jet of plasma radicals toward the wafer edge during edge bead removal. The details of the components of EBR system 125 will be discussed with reference to FIGS. 2A-1 through 6C. In addition to the chuck and the nozzle housing, the EBR system 125 includes an exhaust (not shown) to promptly remove the radicals and the residues released from the wafer edge. Prompt removal of the residues and radicals ensures that the residues do not contaminate the wafer surface and the radicals do not damage the devices formed on the wafer surface. The EBR system 125 with the nozzle allows for minimal hardware changes while significantly improving the etch rate of the edge bead from the wafer edge.

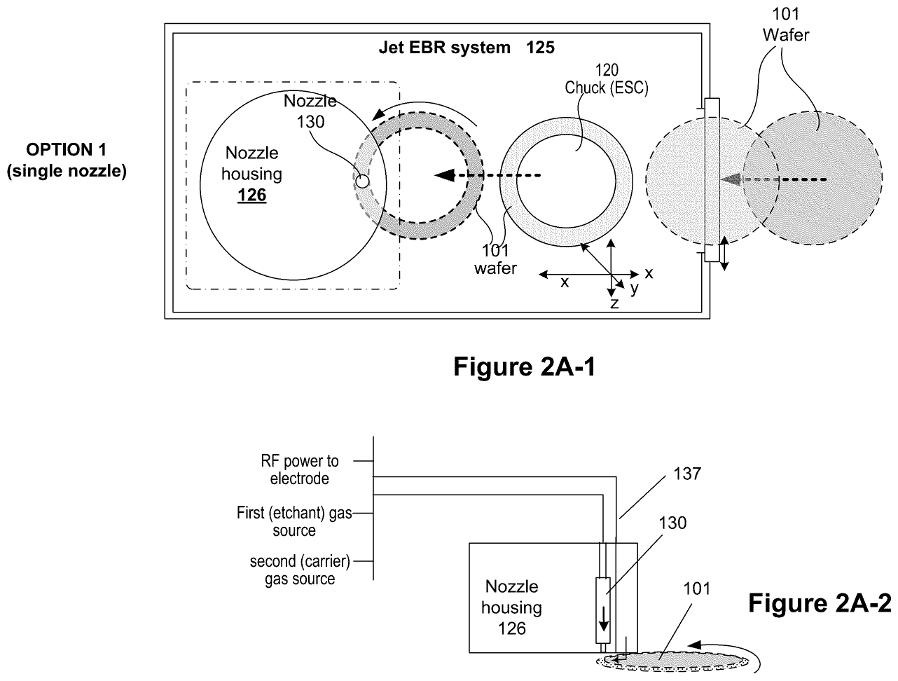

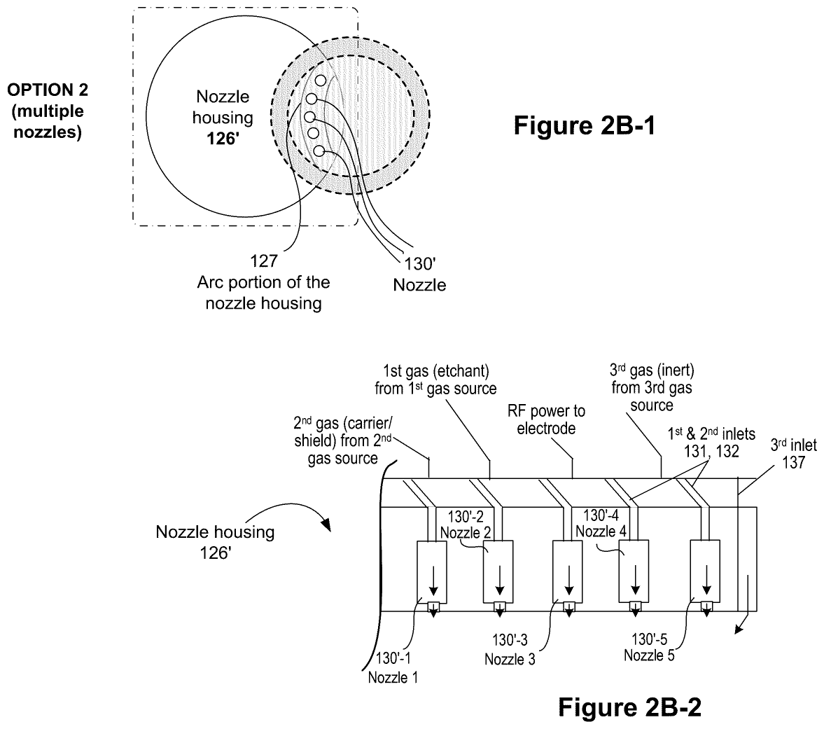

FIG. 2A-1 illustrates the movement of the wafer into the EBR system 125 for edge bead removal, in one implementation. As noted, the EBR system 125 includes a chuck 120 and a nozzle housing 126 in which a nozzle 130 is disposed. The nozzle is configured to provide pressurized plasma radicals of an etchant gas for edge bead removal at the wafer edge. The wafer is moved into the EBR system 125 by an end-effector of a robot of the EFEM 104, for example. The chuck 120 provides a support surface on which the wafer is received and is configured to move along an x-axis, a y-axis and a z-axis so as to bring the edge of the wafer under the nozzle 130 of the nozzle housing 126, for plasma radical application. In this implementation, the nozzle housing with the nozzle is stationary. The nozzle 130 is configured to apply radio frequency (RF) power to generate plasma of an etchant gas received within the nozzle 130. The radicals of the plasma are then carried out of the nozzle at high pressure by a carrier gas and applied to the edge of the wafer 101 positioned below the nozzle 130. The chuck 120 with the wafer 101 received thereon is rotated along the x-axis so as to expose different portions of the edge of the wafer to the plasma radicals for effective etching of the edge bead.

FIG. 2A-2 illustrates a simplified side view rendition of the nozzle housing of the EBR system 125 used in the edge bead removal of the wafer 101. The nozzle 130 is coupled to a first gas source to receive a first gas, and a second gas source to receive a second gas. The first gas includes an etchant gas (e.g., Oxygen), and the second gas is an inert gas. The nozzle 130 includes a pair of electrodes connected to an RF power source so as to apply RF power to the etchant gas to generate plasma. In addition to the etchant gas, the first gas may include a carrier gas. The carrier gas pushes the plasma radicals out of the nozzle 130 toward the wafer edge that is received underneath the nozzle 130. The carrier gas of the first gas is an inert gas and may be the same or different from the inert gas included in the second gas. The second gas is directed out of the nozzle straight down so as to not perturb the plasma radicals coming out of the nozzle but to encircle the plasma radicals. The second gas acts as a shield for the plasma radicals preventing recombination or dispersion of the plasma radicals while ensuring focused application of the radicals over the wafer edge.

A third gas from a third gas source is supplied from a third inlet 137 into a third channel defined adjacent to the nozzle 130 in the nozzle housing 126. A third opening is defined in the nozzle housing 126 so as to cover an inside area of the wafer when the wafer is received under the nozzle housing for edge bead removal. The force with which the third gas is applied is defined so as to be sufficient to direct the plasma radicals away from the inside area and toward the edge of the wafer but not too much to cause the plasma radicals to be pushed away from the wafer edge prematurely. The third gas may be an inert gas and may be same as the inert gas of the first and/or the second gas or may be different. As the wafer is rotated, different portions of the wafer edge are exposed to the plasma radicals. The pressurized plasma radicals applied to the wafer edge act to release the edge bead from the wafer edge. The released residues from the edge bead and the plasma radicals are promptly removed out of the EBR system 125 using an exhaust so as to prevent contamination or damage to the wafer surface. In the implementation illustrated in FIGS. 2A-1 and 2A-2, the nozzle housing 126 is shown to include a single nozzle 130.

FIGS. 2B-1 and 2B-2 illustrate a simplified block diagram of a nozzle housing 126′ in which a plurality of nozzles 130′ is disposed, in one implementation. FIG. 2B-1 illustrates an overhead view and FIG. 2B-2 illustrates a side view of the nozzle housing 126′ disposed in the EBR system 125′. A plurality of nozzles (130′-through 130′-5) is arranged in the nozzle housing 126′ along an arc 127 with each nozzle 130′ separated from an adjacent nozzle 130′ by a pre-defined distance. The arc 127 is defined to match with a contour of the edge of the wafer 101 so that when the wafer edge is brought under the nozzles 130′ of the nozzle housing 126′, the plasma radicals can simultaneously flow out of the plurality of nozzles 130′ toward the wafer edge and work toward releasing the edge bead on the wafer edge. In one implementation, the pre-defined distance of separation between any pair of adjacent nozzles 130 is between about 5 mm and about 50 mm. In one implementation, a set of five nozzles 130′ are disposed along the arc 127′ defined in the nozzle housing 126′. Each of the nozzles 130′ are similar in structure to the nozzle 130 illustrated in FIGS. 2A-1 and 2A-2, and are connected to a first gas source through a first inlet, a second gas through a second inlet, and to RF power source through a match network so that RF power can be applied to an etchant gas included in the first gas to generate the plasma radicals. Further, as with the implementation illustrated in FIGS. 2A-1 and 2A-2, a third inlet 137 coupled to a third gas source is configured to provide a third gas into a third channel defined adjacent to the nozzles 130′ in the nozzle housing 126′. The third gas is supplied through a third opening defined in the nozzle housing 126′ so as to cover an inside area of the wafer when the wafer is positioned under the nozzle housing 126′ during edge bead removal.

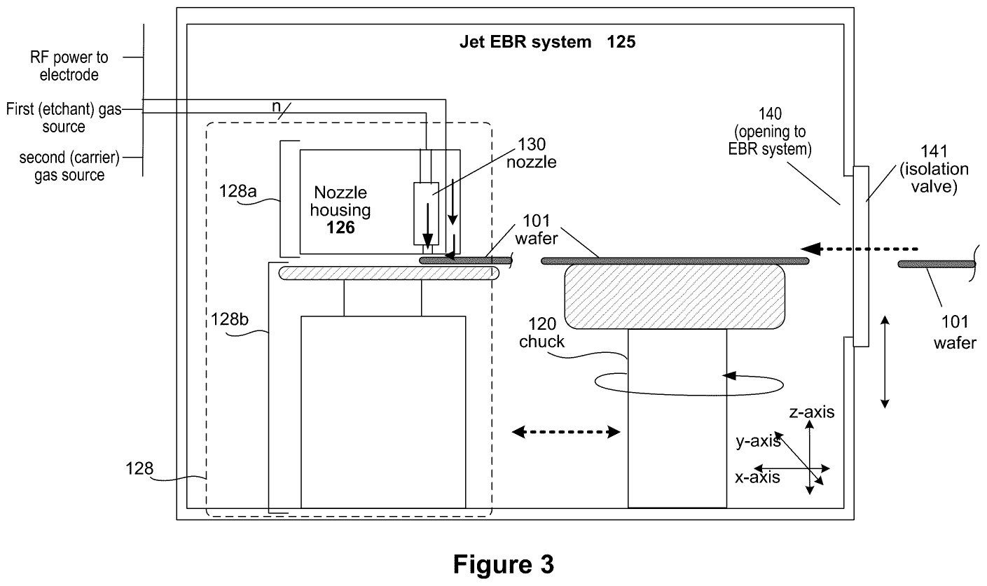

FIG. 3 illustrates a simplified block diagram of the EBR system 125 showing the different components of the EBR system 125 used during edge bead removal from the wafer edge of a wafer 101 received in the EBR system 125, in one implementation. The EBR system 125, in this implementation, relates to a single nozzle implementation discussed with reference to FIGS. 2A-1 and 2A-2, but can be easily extended to include more than one nozzle 130 in the nozzle housing 126 to improve edge bead removal process. The EBR system 125 includes a clamping chuck (or simply referred to as “chuck”) 120 and a nozzle housing 126. Additionally, the EBR system 125 includes an exhaust (not shown) to promptly remove the plasma radicals and residues released from the wafer edge during edge bead removal operation performed in the EBR system 125. In one implementation, the chuck 120 is an electrostatic chuck that is configured to receive and hold the wafer in place, and is also configured to move along an x-axis, a y-axis and/or a z-axis. In another implementation, the chuck 120 is a vacuum chuck that is configured to receive and hold the wafer in place, and is also configured to move along an x-axis, y-axis and/or a z-axis. The wafer is moved into the EBR system 125 via an opening 140 operated by an isolation valve 141. The wafer is moved into the EBR system 125 using an end-effector of the robot 105 of the EFEM 104. The EBR system 125 is being operated at atmospheric conditions.

The isolation valve 141 is initially in a disengaged state providing access to the EBR system 125. Once the wafer 101 is moved onto the chuck 120, the isolation valve 141 is engaged to close the opening. The various components of the wafer processing system 100 including the isolation valves at the load ports 113, EFEM 104, the robot 105 of the EFEM 104, loadlocks 108, VTM 102, the robot of the VTM, the process modules accessed via the VTM 102 and the various components of the EBR 125 (e.g., the isolation valve, the chuck 120 and the nozzle housing 126) are all connected to a controller (not shown) to coordinate movement of the wafer 101 into and out of the different process modules, the EBR system 125, the VTM 102, the EFEM 104, the loadlocks 108, and activation of the different processes including the edge bead removal process. The EBR system 125 includes the chuck 120 and a nozzle unit 128 in which a nozzle housing 126 is integrated. In one implementation, the chuck 120 is a moveable unit and the nozzle housing 126 disposed in the nozzle unit 128, is stationary. In this implementation, the chuck 120 with the wafer 101 received thereon is moved along an x-axis and/or y-axis to bring the edge of the wafer 101 under the nozzle(s) 130 of the nozzle housing 126. The nozzle unit 128 includes a upper housing portion 128a and a lower housing portion 128b. The upper housing portion 128a includes the nozzle housing 126 with the nozzle(s) 130 defined therein. The upper housing portion 128a is disposed over the lower housing portion 128b such that a gap exists there-between to accommodate a portion of the wafer 101 received for edge bead removal. The size of the gap is defined so that no part of the wafer 101, when received in the gap, touches any surface of the upper housing portion 128a or the lower housing portion 128b of the nozzle unit 128 thereby allowing the wafer to rotate freely about a horizontal axis to expose different portions of the wafer edge to a focused application of the plasma radicals. In one implementation, the gap between the upper housing portion 128a and the lower housing portion 128b is defined to be between about 0.8 mm and about 2 mm. In this implementation, the lower housing portion 128b of the nozzle unit 128 may be coupled to a sidewall and/or bottom of the process chamber of the EBR system 125, and a portion of the upper housing portion 128a may be attached to the sidewall of the process chamber of the EBR system 125 and the remaining portion of the upper housing portion 128a may be designed to move along x, y, and/or z-axes so that the nozzle housing 126 with the nozzle 130 can be moved over the chuck 120 to position the nozzle(s) 130 over the wafer edge.

In another implementation, the chuck 120 may be a stationary unit and the nozzle housing 126 of the nozzle unit 128 may be a movable unit. In this implementation, the nozzle housing 126 may be configured to move about an x-axis, a y-axis and a z-axis so as to bring the nozzle 130 over the wafer 101 received on the chuck 120. In one implementation, once the nozzle 130 is positioned over the edge of the wafer 101, the nozzle housing 126 is configured to rotate about the x, y axes so that the nozzle 130 can cover the entirety of the wafer edge circumference. In one implementation, the nozzle unit 128 may include only the upper housing portion 128a with the nozzle housing 126. A portion of the nozzle housing 126 may be attached to a sidewall of the process chamber of the EBR system 125 and the remaining portion may be configured for moving about the x, y, z axes. In an alternate implementation, the chuck 120 and the nozzle housing 126 of the nozzle unit 128 may both be designed as moveable units. In this implementation, the nozzle housing 126 may be moved to position the nozzle 130 over a portion of the edge of the wafer 101 received on the chuck 120. Once the nozzle 130 is positioned over the wafer edge, the chuck 120 is configured to spin about the horizontal axis so that the nozzle 130 can cover the entirety of the wafer edge circumference. The EBR system 125 includes an exhaust (not shown) to promptly remove the residues released from the wafer edge and the plasma radicals.

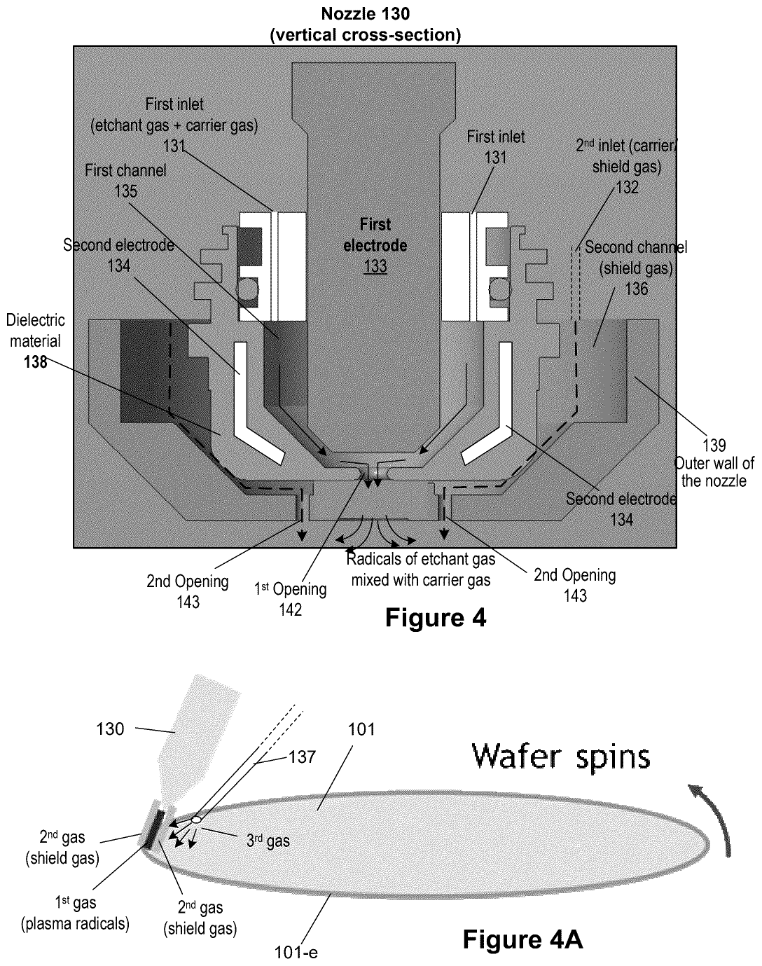

FIG. 4 illustrates an expanded, vertical cross-sectional view of a nozzle 130 used in the EBR system 125 for removing edge bead from the edge of a wafer, in one implementation. The nozzle 130 includes a first electrode 133 defined in the center. A dielectric material 138 is disposed to surround the first electrode 133 so that a first channel 135 is defined between the first electrode 133 and the dielectric material 138. The first channel 135 is connected to a first gas source (not shown) through a first inlet 131 defined at a first end, and to a first opening 142 at a second end defined at the bottom of the nozzle 130. The first channel 135 is configured to receive a first gas from the first gas source through the first inlet 131. The first gas may be a mixture of an etchant gas, such as Oxygen, and an inert gas, such as Argon or Helium. The etchant gas is used to generate the plasma and the inert gas is used to carry plasma radicals of the etchant gas through the first opening 142. A second electrode 134 is embedded within the dielectric material 138 and surrounds the first electrode 133. The dielectric material 138 acts as a barrier to metal surfaces so as to prevent arcing and metal contamination when RF power is applied.

The dielectric material 138 disposed within the nozzle 130 further defines a second channel 136 between the dielectric material 138 and an outer wall of the nozzle 139. The second channel 136 is coupled to a second gas source through a second inlet 132 defined at a first end, to receive a second gas, and a second opening 143 is defined at a second end defined at the bottom of the nozzle 130. The second opening 143 is defined adjacent to and surrounds the first opening 142. The second opening 143 may be a single opening or a plurality of openings that surround the first opening 142. The second gas is an inert gas, such as Argon, Helium, etc. The second channel 136 creates a separate gas path for the second gas and the second opening 143 in the bottom of the nozzle 130 directs the second gas to flow straight down without perturbing the plasma radicals flowing through the first opening 142. The second gas exiting the second opening 143 acts as a shield for the plasma radicals mixed with the carrier gas exiting the first opening 142 by encircling the mixture of plasma radicals and the carrier gas.

FIG. 4A illustrates a view of the plasma radicals with the shield gas surround directed toward the edge of the wafer 101. The shield gas prevents the plasma radicals from dispersing or recombining with the surrounding air, enabling focused application of the plasma radicals to the wafer edge 101-e. As the wafer spins about a horizontal axis, different portions of the wafer edge 101-e get exposed to the plasma radicals, which effectively acts to remove the edge bead accumulating at the wafer edge 101-e. A third gas received in a third channel defined adjacent to the nozzle 130 within the nozzle housing 126 is supplied through a third opening over the surface of the wafer 101. The third gas is supplied with sufficient force to keep the plasma radicals over the wafer edge 101-e to ensure that the wafer edge 101-e gets sufficiently exposed to the plasma radicals.

Referring to FIG. 4, in one implementation, the second electrode 134 is embedded in the dielectric material 138 such that the second electrode 134 is oriented parallel to the first electrode 133 disposed in the center. In an alternate implementation, the second electrode 134 embedded in the dielectric material 138 is oriented perpendicular to the first electrode 133. In yet another implementation, the second electrode 134 is shaped to follow a contour of the dielectric material 138 and is oriented so as to be parallel to the first electrode 133. Irrespective of the orientation, the second electrode 134 is disposed at a pre-defined distance from the first electrode 133, wherein the pre-defined distance is determined to enable generation of plasma of the first gas received in the first channel 135. In one implementation, the first electrode 133 is made of metal. In another implementation, the first electrode 133 and the second electrode 134 are made of same material. In an alternate implementation, the first electrode 133 is made of different material than the second electrode 134.

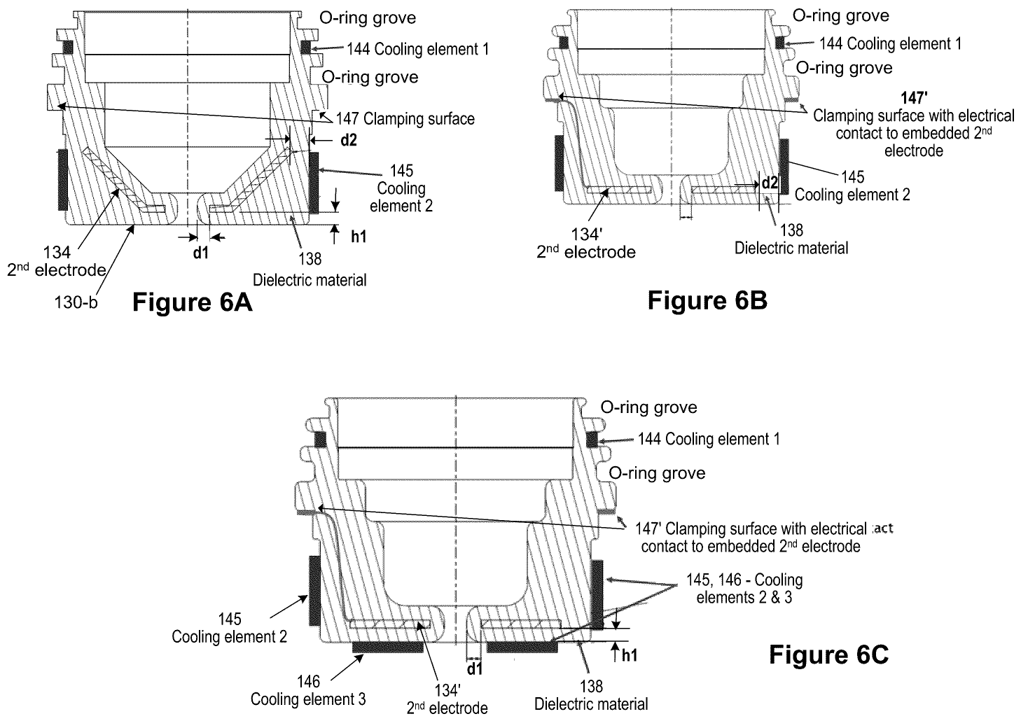

The material used for the second electrode 134 is chosen so as to withstand high temperatures. In one implementation, the material used for the second electrode 134 is chosen to have a coefficient of thermal expansion (CTE) that matches the CTE of the dielectric material 138 in which the second electrode 134 is embedded. In one implementation, the first and the second electrodes 133, 134, are made of any one of Tungsten, Molybdenum or Platinum and the dielectric material 138 is made of any one of Aluminum Nitride, Aluminum Oxynitride, Silicon Nitride, Aluminum Oxide or Yttrium Oxide. In one implementation, the dielectric material 138 and/or the first electrode 133 are cooled using one or more cooling elements. In one implementation, the cooling element is disposed in a region that is proximate to the second electrode. Details of the cooling element will be described with reference to FIGS. 6A-6C.

In one implementation, the first electrode 133 disposed in the center of the nozzle 130 is coupled to a radio frequency (RF) power source and the second electrode 134 is grounded via a match network. In an alternate implementation, the first electrode 133 is grounded and the second electrode is 134 is coupled to the RF power source via a match network. In yet another implementation, the first electrode 133 and the second electrode 134 are coupled to the RF power source via a match network. In this implementation, neither the first electrode 133 nor the second electrode 134 is grounded. A differential voltage is applied to the first electrode 133 and the second electrode 134. For instance, for an input voltage of 2V, the voltage applied to the first electrode will be +V and the voltage applied to the second electrode will be −V (i.e., each electrode is provided with one half of the input voltage). A differential drive is coupled to the RF power source (not shown) and is used to switch the RF power input between the two electrodes (first electrode 133, second electrode 134). In one implementation, the differential drive may be an isolation transformer with secondary windings used to provide the differential voltage.

In one implementation, the first gas includes a mixture of an etchant gas and a carrier gas. In one implementation, the etchant gas is Oxygen and the carrier gas is Argon (i.e., an inert gas). In another implementation, the etchant gas is Oxygen and the carrier gas is Helium (i.e., an inert gas). It should be noted that the aforementioned examples of etchant gas and carrier gas are provided as mere examples and should not be considered restrictive. Depending on the type of films (i.e., residues) of the edge bead that are being targeted for removal, the carrier gas may be any stable, inert gas such as Argon or Helium and the etchant gas may be Fluorine, Chlorine, or some other halogen, or Hydrogen.

In one implementation, the nozzle topology is defined so as to supply high density plasma radicals to the wafer edge in order to achieve high precision edge bead removal. In one implementation, the flow rate of the etchant gas in the first gas is defined to be between 100 standard cubic centimeters per minute (sccm) and about 300 sccm and the flow rate for the carrier gas flow is defined to be between about 1000 sccm and 30,000 sccm.

The topology of the nozzle provides an efficient and effective way of removing the edge bead from the wafer edge using a simple process chamber that includes minimal hardware. The plasma is generated remotely and provided to the wafer edge. In addition to the first and the second gas being applied to the wafer edge, a third gas may also be provided from a third channel defined adjacent to the nozzle. The third gas acts as a gas curtain pushing the first gas enveloped in the second gas away from the center of the wafer and toward the wafer edge so as provide focused application of the plasma radicals at the wafer edge. The simple design allows the process chamber to be kept light weight and small enabling the process chamber to be stacked on other existing modules (e.g., loadlock) leaving no additional footprints.

In some implementations, there may be ‘n’ number of nozzles (wherein ‘n’ is an integer) within the nozzle housing 126 providing the plasma radicals simultaneously to cover a larger area of the wafer edge. In some implementations, the nozzle housing may include 3 or 5 or 7 or 9 nozzles disposed proximate to one another and disposed along an arc defined in the nozzle housing 126. The arc is defined to match the curvature of the substrate edge. Although various implementations have been described herein with reference to the EBR system using a nozzle, the implementations are not limited to nozzle operated EBR system and that other non-nozzle tools/parts may also be engaged for edge bead removal.

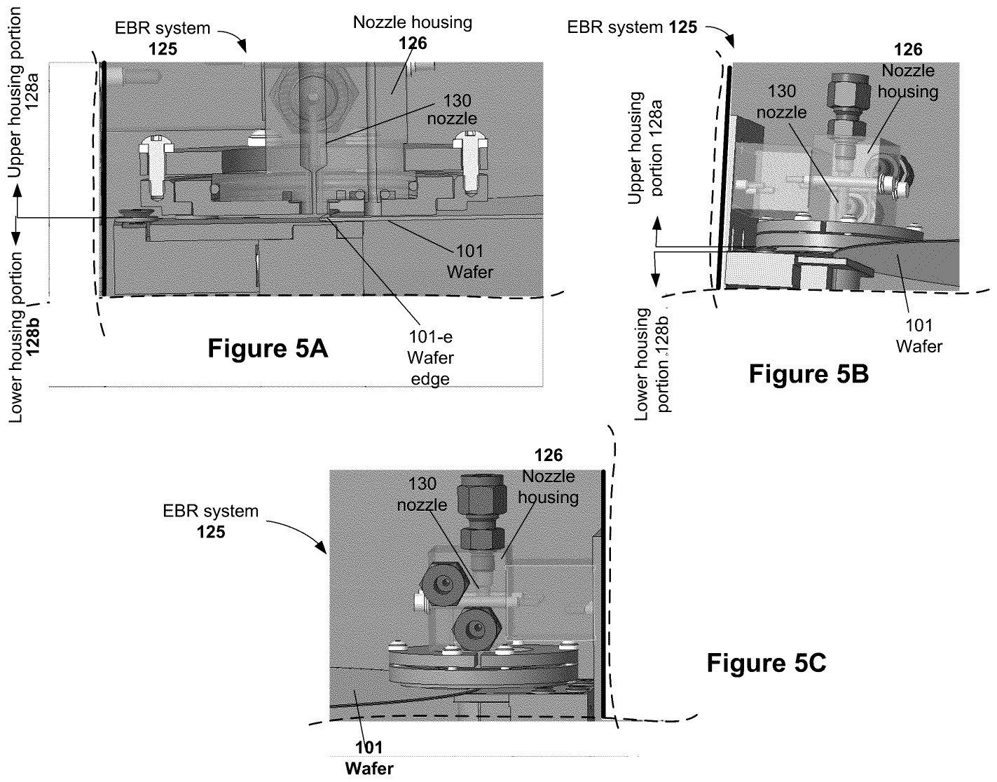

FIGS. 5A-5C illustrate different profile views of the EBR system 125 showing the wafer edge 101-e of the wafer 101 received under the nozzle 130 of the nozzle housing 126, in one example implementation. FIG. 5A illustrates a frontal perspective view as the wafer is being moved into position underneath the nozzle 130, FIG. 5B illustrates a side perspective view, and FIG. 5C illustrates a full side perspective view with the wafer 101 in position underneath the nozzle 130 of the nozzle housing 126 within the EBR system 125. The wafer is received on the support surface (e.g., top surface of a stage) of a chuck (e.g., electrostatic chuck or vacuum chuck—not shown in FIGS. 5A-5C) and moved into position under the nozzle 130 of the nozzle housing 126. The gap in the nozzle housing 126 between the upper housing portion 128a and the lower housing portion 128b of the nozzle unit 128 of the EBR system 125 is sufficient to insert the wafer edge 101-e without touching any surface or part of the upper and the lower housing portions 128a, 128b. FIGS. 5A-5C show the upper housing portion and the lower housing portion (128a, 128b) of the nozzle unit 128 disposed in the EBR system 125 both being attached to a sidewall of the process chamber of the EBR system 125, in one implementation. The nozzle housing 126 is defined in the upper housing portion 128a. In this implementation, the nozzle housing 126 may be stationary and the chuck on which the wafer is received may be a moveable unit. In alternate implementations, the chuck may be a stationary unit and the nozzle housing 126 with the nozzle 130 may be a moveable unit. In this implementation, the nozzle housing 126 with the nozzle 130 is configured to move around the circumference of the wafer to allow the plasma radicals exiting the nozzle 130 to clean the edge of the wafer. In one implementation, sensors may be provided in the nozzle housing, or in the upper housing portion, or in the lower housing portion of the process chamber of the EBR system 125 to measure the gap(s) between the wafer support defined on the chuck 120 and the nozzle(s) 130 of the nozzle housing 126 and the position of the nozzle(s) 130 in relation to the edge of the wafer. The measurement is done in real time. and the positioning of either the nozzle housing 126 (when the nozzle housing 126 is the moveable unit) or the chuck (when the chuck is the moveable unit) is controlled in real time so as to position the nozzle 130 over the edge portion of the wafer for edge bead removal operation.

FIGS. 6A-6C illustrate a portion of the nozzle 130 within a nozzle housing that employs one or more cooling elements to improve usage life and to allow high power operation for edge bead removal, in some implementations. FIG. 6A illustrates a first cooling element 144 defined above a clamping surface 147 used to clamp the nozzle to the nozzle housing 126, in one implementation. One or more O-ring groves are provided in the nozzle 130 into which O-rings are received to allow the nozzle 130 to snugly fit into the nozzle housing 126. In the implementation illustrated in FIGS. 6A-6C, a first O-ring grove is defined above the first cooling element 144 and a second O-ring grove is defined below the first cooling element 144 and between the first cooling element 144 and the clamping surface 147. A second cooling element 145 is defined on a lateral side at an outer diameter of the dielectric material 138 so as to encircle a region of the dielectric material 138 where the second electrode 134 is embedded. In one implementation, a first end of the second electrode 134 is defined to be at a distance ‘d1’ from an inner radius of the dielectric material 138, wherein the inner radius is defined to be adjacent to the first opening 142 (shown in FIG. 4) of the nozzle 130. In one implementation, the distance d1 is defined to be between about 0.1 mm and about 1.0 mm. In one implementation, the second cooling element 145 is disposed at a distance ‘d2’ from a second end of the second electrode 134. In one implementation, the separation distance d2 may be defined to be between about 0.1 mm and about 1.0 mm. In one implementation, the second electrode 134 is disposed so that a bottom surface of the second electrode 134 is defined at a height ‘h1’ from a bottom surface of the dielectric material 138. In one implementation, the height h1 may be defined to be between about 0.1 mm and about 1.0 mm. In the implementation illustrated in FIG. 6A, the second electrode 134 is defined to have a contour that matches the contour of a bottom portion of the first electrode 133 and is disposed within the dielectric material 138 so as to be parallel to the bottom portion of the first electrode 133. In addition to the first and the second cooling elements, 144, 145, the nozzle may include a central cooling element (not shown) that is incorporated within the first electrode.

FIG. 6B illustrates an alternate shape of the second electrode 134′ embedded in the dielectric material 138, in one implementation. In this implementation, the second electrode 134′ has a straight line topology and is disposed within the dielectric material 138 so as to be parallel to a bottom portion of the first electrode 133. As with the implementation illustrated in FIG. 6A, the first end of the second electrode 134 is defined at a distance d1 from the inner radius of the dielectric material 138, and the second cooling element 145 is defined on a lateral side at an outer diameter of the dielectric material 138 so as to be at a distance d2 from a second end of the second electrode 134. Further, an electrical contact is provided at the clamping surface 147′ to connect the second electrode 134′ to the RF power. In this implementation, the first electrode 133 may be grounded.

FIG. 6C illustrates another implementation of the nozzle illustrated in FIG. 6B. In this implementation, in addition to the various components defined in the nozzle, the nozzle may include a third cooling element 146 disposed along a bottom side of the dielectric material 138. The second electrode 134′ is similar in shape and disposed in the same orientation as illustrated in FIG. 6B. The first, the second and the third cooling elements 144, 145, 146, may be configured for water cooling or evaporative fluid cooling. The first electrode 133 is disposed in the center and may have a profile with straight angled edges, as shown in FIG. 6A, or rounded edges, as shown in FIGS. 6B and 6C. Further, the width of the first electrode 134 may be based on the width of the nozzle 130 and may be narrower or wider.

The various implementations described herein provide a nozzle with dual electrodes that are powered by RF power and are therefore designed to support power and high heat loads. Even with the high power and heat loads, no arc is delivered to the wafer. Instead, plasma radicals are generated between the two RF electrodes and directed toward the wafer edge by means of pressurized jet flow. The design uses a dielectric barrier to prevent arcing and metal contamination. Chemical compatibility with the plasma chemistry is achieved. The dielectric material and the electrode material are chosen to sustain high temperature operation and provide high density plasma radicals that can be applied at high pressure through the nozzle openings. Damage to the second electrode embedded in the dielectric material is minimized or eliminated by choosing the material for the second electrode with CTE that matches the CTE of the dielectric material. The dielectric material is a ceramic and is chosen for its desirable breakdown voltage, high resistance to thermal shock, high thermal conductivity, desirable heat capacity, and high temperature operation. Cooling elements are provided to cool the surface so as to extend power delivery capability and hence usage life of the nozzle. The various advantages of using the nozzle based EBR system is fast time, for cleaning the wafer edge, constant heating and cooling, and when used with a relatively high pressure gas a higher reaction product density is possible. The plasma jet topology of the nozzle also offers substantial cost savings in hardware and is capable of achieving high etch rate by supporting high power density into the plasma without inflicting thermally or chemically induced damage.

The foregoing description of the various implementations has been provided for purposes of illustration and description. It is not intended to be exhaustive or to limit the invention. Individual elements or features of a particular implementation are generally not limited to that particular implementation, but, where applicable, are interchangeable and can be used in a selected implementation, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A nozzle disposed in a housing defined in an upper portion of a process chamber used for processing a wafer, the nozzle configured for removing edge bead accumulated on an edge of the wafer, comprising:
a first electrode defined in a center of a body of the nozzle;
a dielectric material disposed to surround the first electrode within the body;
a first channel defined between the first electrode and the dielectric material, a first end of the first channel is coupled to a first gas source through a first inlet to receive a first gas into the first channel and a second end defined at a bottom of the first channel includes an opening;
a second electrode embedded within the dielectric material; and
a radio frequency (RF) power source coupled to the nozzle and configured to provide RF power to generate plasma of the first gas received in the first channel defined between the first electrode and the second electrode,
wherein the opening in the first channel is configured, during operation, to provide pressurized flow of radicals of the plasma generated in the first channel toward a portion of the edge of the wafer positioned below the nozzle of the process chamber.

2. The nozzle of claim 1, further includes a second channel defined between the dielectric material and an outer wall of the nozzle,
wherein a first end of the second channel is connected to a second inlet coupled to a second gas source to receive a second gas into the second channel, a second end of the second channel includes a second opening disposed at a bottom of the nozzle and oriented to be adjacent to and surround the opening of the first channel, the second gas flowing out of the second opening forming a shield around the radicals of the plasma flowing out of the opening of the first channel.

3. The nozzle of claim 2, wherein the second gas is an inert gas, and wherein the inert gas is one of Argon or Helium.

4. The nozzle of claim 1, wherein at least a portion of the second electrode is disposed proximal to the opening of the first channel.

5. The nozzle of claim 1, wherein the first electrode is coupled to the RF power source through a match network and the second electrode is electrically grounded.

6. The nozzle of claim 1, wherein the first electrode is electrically grounded and the second electrode is coupled to the RF power source through a match network.

7. The nozzle of claim 1, wherein the first electrode and the second electrode are coupled to the RF power source through corresponding match network, the RF power source coupled to a differential drive configured to switch supply of RF power input between the first electrode and the second electrode, wherein the differential drive is an isolation transformer.

8. The nozzle of claim 1, wherein chemical and thermal property of the dielectric material matches chemical and thermal property of a material used to define the second electrode.

9. The nozzle of claim 1, wherein a coefficient of thermal expansion of the dielectric material matches a coefficient of thermal expansion of material used to define the second electrode.

10. The nozzle of claim 1, wherein the first and the second electrodes are any one of Tungsten, or Molybdenum, or Platinum; and
wherein the dielectric material is any one of Aluminum Nitride, or Aluminum Oxynitride, or Silicon Nitride, or Aluminum Oxide, or Yttrium Oxide.

11. The nozzle of claim 1, further includes a first cooling element defined within the first electrode and a second cooling element defined at an outer diameter of the dielectric material, the second cooling element designed to cover at least a portion of an outer sidewall of the dielectric material in a region where the second electrode is disposed, the first and the second cooling elements are configured for water cooling or coil cooling.

12. The nozzle of claim 11, further includes a third cooling element defined on the outer sidewall along a bottom portion of the dielectric material proximal to a second opening of a second channel defined between the dielectric material and an outer wall of the nozzle, the third cooling element is designed for water cooling or coil cooling.

13. The nozzle of claim 1, wherein the first gas includes a mixture of an etchant gas and a carrier gas, the etchant gas used to generate the radicals of the plasma, wherein the etchant gas is Oxygen.

14. The nozzle of claim 1, wherein the housing includes a plurality of nozzles including the nozzle, the plurality of nozzles is defined along an arc, each nozzle of the plurality of nozzles separated from an adjacent nozzle of the plurality of nozzles by a predefined distance,
wherein a profile of the arc defined in the housing matches a profile of a portion of the edge of the wafer received for removal of the edge bead, and
wherein the radicals of the plasma applied simultaneously by the plurality of nozzles cover the portion of the edge of the wafer.

15. The nozzle of claim 1, wherein the wafer is received on a clamping chuck defined in the process chamber, the clamping chuck is a movable unit configured to move along an x-axis, a y-axis and a z-axis to allow the edge of the wafer to be brought below the nozzle, and wherein the nozzle is a stationary unit, and wherein the clamping chuck is an electrostatic chuck or a vacuum chuck.

16. The nozzle of claim 1, wherein the wafer is received on a clamping chuck defined in the process chamber, the clamping chuck is a stationary unit and the nozzle is a moveable unit configured to move along an axis so as to apply radicals of the plasma to an entirety of the edge of the wafer, and wherein the clamping chuck is an electrostatic chuck or a vacuum chuck.

17. The nozzle of claim 1, wherein the first gas includes an etchant gas and a carrier gas, the etchant gas used to generate the radicals of the plasma.

18. A wafer processing system having an equipment front end module (EFEM), one or more loadlocks, a vacuum transfer module and a plurality of process chambers for processing a wafer, wherein a process chamber of the plurality of process chambers is used for removal of edge bead from an edge of the wafer, the process chamber comprising:
a clamping chuck defined in a lower portion of the process chamber, the clamping chuck configured to provide a support surface for the wafer received for processing;
a nozzle disposed in a housing defined in an upper portion of the process chamber, the housing oriented over the clamping chuck, the nozzle including,
a first electrode defined in a center of a body of the nozzle;
a dielectric material disposed to surround the first electrode within the body;
a first channel defined between the first electrode and the dielectric material, a first end of the first channel is coupled to a first gas source through a first inlet to receive a first gas into the first channel and a second end defined at a bottom of the first channel includes an opening;
a second electrode embedded within the dielectric material; and
a radio frequency (RF) power source coupled to the nozzle and configured to provide RF power to generate plasma of the first gas received in the first channel defined between the first electrode and the second electrode,
wherein the opening in the first channel is configured, during operation, to provide pressurized flow of radicals of the plasma generated in the first channel toward the edge of the wafer positioned below the nozzle of the process chamber.

19. The wafer processing system of claim 18, wherein the process chamber is disposed over the one or more loadlocks of the wafer processing system, the process chamber accessed through a chamber opening defined in the EFEM of the wafer processing system, wherein the chamber opening is controlled by an isolation valve.

20. The wafer processing system of claim 18, further includes a second channel defined between the dielectric material and an outer wall of the nozzle,
wherein a first end of the second channel is connected to a second inlet coupled to a second gas source to receive a second gas into the second channel, a second end of the second channel includes a second opening disposed at a bottom of the nozzle and oriented to be adjacent to and surround the opening of the first channel, the second gas flowing out of the second opening forming a shield around the radicals of the plasma flowing out of the opening of the first channel.

21. The wafer processing system of claim 18, wherein the housing with the nozzle is a stationary unit and the clamping chuck is a moveable unit, the clamping chuck configured to move along an x-axis, a y-axis or a z-axis to allow the edge of the wafer received thereon to be oriented under the opening of the nozzle in the housing, during operation, and wherein the clamping chuck is an electrostatic chuck or a vacuum chuck.

22. The wafer processing system of claim 18, wherein the housing with the nozzle is a movable unit and the clamping chuck is a stationary unit, the housing with the nozzle configured to move along an x-axis, a y-axis, or a z-axis to allow the nozzle to be positioned above an edge of the wafer, during operation, and wherein the clamping chuck is an electrostatic chuck or a vacuum chuck.

23. The wafer processing system of claim 18, wherein the RF power source is coupled to the first electrode via a match network and the second electrode is electrically grounded.

24. The wafer processing system of claim 18, wherein the first electrode is electrically grounded and the RF power source is coupled to the second electrode via a match network.

25. The wafer processing system of claim 18, wherein the RF power source is coupled to the first electrode and the second electrode via a match network, a differential drive coupled to the RF power source is configured to switch supply of RF power input between the first electrode and the second electrode, wherein the differential drive is an isolation transformer.
